(19) United States
(12) Patent Application Publication
(10) Pub. No.: US 2021/0144878 A1
(43) Pub. Date: May 13, 2021

(54) SLIDING ASSEMBLY FOR NON-PERMANENT INSTALLATIONS

(71) Applicant: HONGFUJIN PRECISION ELECTRONICS(TIANJIN)CO.,LTD., Tianjin (CN)

(72) Inventors: CHANG-JU WU, New Taipei (TW); CHEN-SHENG TANG, New Taipei (TW)

(21) Appl. No.: 16/693,700

(22) Filed: Nov. 25, 2019

(30) Foreign Application Priority Data
Nov. 13, 2019 (CN) 201911107999.9

(51) Int. Cl. H05K 7/18

(52) U.S. Cl. CPC H05K 7/183

(57) ABSTRACT

A strengthened sliding assembly, for non-permanent storage, and able to function over longer sliding distances includes at least a first sliding rail and a second sliding rail. The first sliding rail includes a first board and a pair of first bending edges. The two first bending edges are positioned on both sides of the first board, which defines two first sliding grooves. The second sliding rail includes a second board and a pair of second bending edges. The two second bending edges are positioned on both sides of the second board. A part of each second bending edge is received in a first sliding groove. The second sliding rail can slide in first sliding grooves relative to first slide rail. The sliding assembly of the disclosure is increased load-bearing capacity and compact structure.

### FIELD

The subject matter herein generally relates to storage assemblies.

### BACKGROUND

Load-bearing devices can have sliding rails which are similar as those in drawers and server racks, so that the objects to be carried and installed can be moved easily into place. As the width of servers becomes wider, sliding rails become more important, and their carrying capacity and strength becomes more important.

An improvement is required.

### BRIEF DESCRIPTION OF THE DRAWINGS

Implementations of the present disclosure will now be described, by way of embodiments, with reference to the attached figures.

FIG. 1 is an exploded view of an embodiment of a sliding assembly.

FIG. 2 is a schematic diagram of an embodiment of the sliding assembly.

FIG. 3 is a side view of an embodiment of the sliding assembly of FIG. 2.

FIG. 4 is a schematic view of the sliding assembly of FIG. 2 extended.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series, and the like.

FIG. 1 illustrates a sliding assembly 100 in accordance with an embodiment of the present disclosure.

In at least one embodiment, the sliding assembly 100 includes a first sliding rail 10, a second sliding rail 20, and a third sliding rail 30.

FIG. 2 illustrates that the first sliding rail 10 includes a first board 11 and a pair of first bending edges 12. The first board 11 is substantially straight. The central portion of the first board 11 is bent along one side to form a first side wall 111. The first side wall 111 is substantially an inverted U-shape. The pair of first bending edges 12 are disposed on two sides of the first board 11 and are bent toward each other. The pair of first bending edges 12 are substantially an inverted L-shape, and are respectively formed with a first sliding groove 13 for the first board 11.

FIG. 3 illustrates that each first bending edge 12 includes a first block 121 and a second block 122. One end of the first block 121 is perpendicularly connected to one end of the first board 11 to form a substantially L-shaped structure with the first board 11. The second block 122 is substantially straight. A first end of the second block 122 is perpendicularly connected to one end of the first block 121 away from the first board 11, and a second end of the second block 122 extends in a direction parallel to the first board 11 and adjacent to another first bending edge 12.

In at least one embodiment, two sides of the first board 11 are bent and extended to form the pair of first bending edges 12. The first side wall 111 of the first board 11, the first block 121, and the second block 122 are disposed on the same side of the first sliding rail 10.

In at least one embodiment, the second block 122 and the first board 11 are disposed on the same side of the first block 121. A length of the second block 122 is smaller than a length of the first board 11. The second block 122, the first block 121, and the first board 11 form a first sliding groove 13, and the first sliding groove 13 is substantially a U shape.

The second sliding rail 20 includes a second board 21 and a pair of second bending edges 22. The second board 21 is substantially straight. Two ends of the second board 21 extend into the first sliding groove 13.

A central portion of the second board 21 away from the first board 11 is bent along one side to form a second side wall 211. The second side wall 211 is substantially an inverted U-shape. The second side wall 211 is spaced apart from the first side wall 111 to form a first channel 212. The first channel 212 sets a first limiting portion (not shown). The second side wall 211 also accommodates the first side wall 111. The two ends of the second board 21 away from the second side wall 211 extend into the first sliding groove 13.

The pair of second bending edges 22 are disposed on both sides of the second board 21, and bent towards each other. A second sliding groove 23 is formed between the second bending edge 22 and the second board 21.

In at least one embodiment, the second bending edge 22 includes a bending portion 222, a third block 223, and a fourth block 224.

The bending portion 222 is substantially straight. The bending portion 222 is disposed in the first sliding groove 13.

A first end of the bending portion 222 is coupled to one end of the second board 21, and a second end of the bending portion 222 extends away from the first block 121 and adjacent to the second side wall 211. In at least one embodiment, the bending portion 222 and the ends of the second board 21 are parallel to each other and overlap with a portion of the second board 21.

The third block 223 is substantially straight. A first end of the third block 223 is perpendicularly coupled to one end of the bending portion 222 away from the second board 21, a second end of the third block 223 extends in a direction parallel to the first block 121 and away from the second board 21.

The fourth block 224 is substantially straight. A first end of the fourth block 224 is perpendicularly coupled to the second end of the third block 223 away from the bending portion 222, a second end of the fourth block 224 extends in a direction parallel to the second board 21 and away from the second board 21.

In at least one embodiment, the second board 21, the bending portion 222, the third block 223, and the fourth block 224 sequentially connected together constitute the second sliding groove 23.

In at least one embodiment, the second side wall 211 and the bending portion 222, the third block 223, and the fourth block 224 are disposed on the same side of the second sliding rail 20. The second bending edge 22 of the second sliding rail 20 cooperates with the first bending edge 12 of the first sliding rail 10. The bending portion 222 is partially received in the first sliding groove 13, and the second sliding rail 20 slides in the first sliding rail 10. The second sliding rail 20 is partially received in the first sliding groove 13 and slides along the first sliding groove 13.

In at least one embodiment, the third sliding rail 30 includes a third board 31 and a pair of third blocks 32. The third board 31 is substantially elongated.

The third board 31 is spaced apart from the second side wall 211 and located at a side of the second side wall 211 away from the first side wall 111. In at least one embodiment, the third board 31 is spaced apart from the second side wall 211 to form a second channel 311. The second channel 311 sets a second limiting portion (not shown).

The pair of third blocks 32 are disposed on both sides of the third board 31, and extended away from each other. Each of the third blocks 32 is substantially L-shaped.

The third block 32 includes a supporting portion 321 and a sliding portion 322. The supporting portion 321 is substantially strip-shaped. One end of the supporting portion 321 is perpendicularly coupled to an end of the third board 31 and extends in a direction parallel to the third block 223 and adjacent to the second board 21.

The sliding portion 322 is substantially strip-shaped. A first end of the sliding portion 322 is perpendicularly coupled to one end of the supporting portion 321 away from the third board 31, and a second end of the sliding portion 322 extends in a direction parallel to the third board 31 and adjacent to the third block 223, the second end of the sliding portion 322 being received in the second sliding groove 23.

In at least one embodiment, the third board 31 is spaced apart from the second side wall 211, and the supporting portion 321 is spaced apart from the fourth block 224. The third board 31 is slightly higher than the fourth block 224, and the sliding portion 322 is at least partially received in the second sliding groove 23. The sliding portion 322 can slide along the second sliding groove 23, and the third sliding rail 30 can slide relative to the second sliding rail 20. The first limiting portion and the second limiting portion disposed in the first channel 212 and the second channel 311 cooperate with each other in such a way as to prevent the second sliding rail 20 from sliding out of the first sliding rail 10. The third sliding rail 30 is also prevented from sliding out of the second sliding rail 20.

FIG. 4 illustrates that the sliding assembly 100 can include the first sliding rail 10, the second sliding rail 20, and the third sliding rail 30. The second sliding rail 20 is nested in the first sliding rail 10 and can extend and retract with respect to the first sliding rail 10. The third sliding rail 30 is nested in the second sliding rail 20 and can extend and retract with respect to the second sliding rail 20.

The sliding assembly 100 includes a three-stage structure, and the sliding assembly 100 has a longer extension length and an adjustable length to accommodate different sized servers.

When the sliding assembly 100 is applied as part of a rack of a server (not shown), the first sliding rail 10 may be first fixed to a side of the rack by a fastener (such as a screw), and the third sliding rail 30 or the second sliding rail 20 can be extended as the case may be. The server can be fixed to the third sliding rail 30, so that the server is received in the rack as both the third sliding rail 30 and the second sliding rail 20 are retracted.

In other embodiments, the sliding assembly 100 is not limited to three sliding rails, the number of sliding rails can be adjusted according to specific needs. For example, the sliding assembly 100 can include two or four or more sliding rails, and the sliding rails are sequentially sleeved to adjust the length of the sliding assembly 100 according to specific conditions.

In other embodiments, the shapes and structures of the first bending edge 12 and the second bending edge 22 are not limited, and may be adjusted according to specific conditions. A sliding rail must be simply able to be accommodated in the sliding groove, and slidable inside the flange. For example, the second bending edge 22 can be designed to be consistent with the structure of the first bending edge 12.

In other embodiments, the first board 11, the second board 21, and the third board 31 can be bent to form a protrusion or a groove, thereby forming a side wall for reinforcing structural strength of the sliding assembly 100.

In other embodiments, when the first board 11, the second board 21, and the third board 31 are sufficiently strong, the first board 11, the second board 21, and the third board 31 do not need to be bent, and the first board 11, the second board 21, and the third board 31 are in a straight plate.

Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the exemplary embodiments described above may be modified within the scope of the claims.

What is claimed is:

1. A sliding assembly, comprising:
a first sliding rail comprising a first board and a pair of first bending edges; wherein the pair of first bending edges are disposed on two sides of the first board, and respectively formed with a first sliding groove with the first board; and
a second sliding rail comprising a second board and a pair of second bending edges; wherein the pair of second bending edges are disposed on two sides of the second board, the second bending edge is partially received in the first sliding groove, and the second sliding rail slides relative to the first sliding rail.

2. The sliding assembly according to claim 1, wherein the first board is bent along one side to form a first side wall, the first bending edge comprises a first block and a second block, one end of the first block is perpendicularly connected to one end of the first board, a first end of the second block is perpendicularly connected to one end of the first block away from the first board, and a second end of the second block extends in a direction parallel to the first board and adjacent to another first bending edge.

3. The sliding assembly according to claim 2, wherein the second board is bent along one side to form a second side wall, the second side wall is spaced apart from the first side wall to form a first channel, and the second side wall accommodates the first side wall.

4. The sliding assembly according to claim 3, wherein a second sliding groove is formed between the second bending edge and the second board, the second bending edge comprises a bending portion, a third block, and a fourth, a first end of the bending portion is arcually coupled to one end of the second board, and a second end of the bending portion extends away from the first block and adjacent to the second side wall.

5. The sliding assembly according to claim 4, wherein a first end of the third block is perpendicularly coupled to one end of the bending portion away from the second board, and a second end of the third block extends in a direction parallel to the first block and away from the second board.

6. The sliding assembly according to claim 5, wherein a first end of the fourth block is perpendicularly coupled to the second end of the third block away from the bending portion, and a second end of the fourth block extends in a direction parallel to the second board and away from the second board.

7. The sliding assembly according to claim 6, wherein the first side wall, the second side wall, the first block, the second block, the bending portion, the third block, and the fourth block are disposed on the same side of the sliding assembly.

8. The sliding assembly according to claim 7, wherein a first limiting portion defines in the first channel, the first limiting portion prevents the second sliding rail from sliding out of the first sliding rail.

9. The sliding assembly according to claim 4, wherein the sliding assembly further comprises a third sliding rail, the third sliding rail comprises a third board and a pair of third blocks, the pair of third blocks are disposed on two sides of the third board, and extended away from each other, the third block is partially received in the second sliding groove, and the third sliding rail slides relative to the second sliding rail.

10. The sliding assembly according to claim 9, wherein the third board is substantially elongated.

11. The sliding assembly according to claim 9, wherein the third board is spaced apart from the second side wall and located at a side of the second side wall away from the first side wall.

12. The sliding assembly according to claim 11, wherein the third board is spaced apart from the second side wall to form a second channel.

13. The sliding assembly according to claim 12, wherein the third block comprises a supporting portion, the supporting portion is substantially strip-shape, one end of the supporting portion is perpendicularly coupled to an end of the third board and extends in a direction parallel to the third block and adjacent to the second board.

14. The sliding assembly according to claim 13, wherein the third block further comprises a sliding portion, the sliding portion is substantially strip-shaped, a first end of the sliding portion is perpendicularly coupled to one end of the supporting portion away from the third board, a second end of the sliding portion extends in a direction parallel to the third board and adjacent to the third block, and being received in the second sliding groove.

15. The sliding assembly according to claim 14, wherein a second limiting portion defines in the second channel, the second limiting portion prevents the third sliding rail from sliding out of the second sliding rail.
